(19) United States
(12) Patent Application Publication
(10) Pub. No.: US 2025/0308937 A1
(43) Pub. Date: Oct. 2, 2025

(54) MANUFACTURING METHOD OF PACKAGE SUBSTRATE

(71) Applicant: AaltoSemi Inc., Jiangsu (CN)

(72) Inventors: Yin-Ju CHEN, Jiangsu (CN); Min-Yao CHEN, Jiangsu (CN); Jiun-Hua CHIUE, Jiangsu (CN); Andrew C. CHANG, Jiangsu (CN); Chung-Hsien YANG, Jiangsu (CN); Chien-Kuang LAI, Jiangsu (CN); Zhen-Hu CHANG, Jiangsu (CN)

(21) Appl. No.: 19/087,819

(22) Filed: Mar. 24, 2025

(30) Foreign Application Priority Data
Mar. 26, 2024 (CN) 202410354267.4

(51) Int. Cl. H01L 21/48

(52) U.S. Cl. CPC H01L 21/486; H01L 21/4853; H01L 21/4857

(57) ABSTRACT

Provided is a method of manufacturing a package substrate, including forming a first circuit layer and a first build-up circuit on a first surface of the first dielectric layer and a second surface thereof opposing the first surface, respectively; and further forming a plurality of second conductive blind vias electrically connected to the first build-up circuit from the first surface after forming a plurality of a first conductive blind vias electrically connected to the first circuit layer and the first build-up circuit from the second surface, thereby solving the problem of high density and fin pitch wiring demand that is not satisfied by the conventional technology.

### BACKGROUND

### 1. Technical Field

The present disclosure relates to a semiconductor device, and more particularly, to a manufacturing method of a package substrate having corresponding conductive blind vias formed on both sides of a dielectric layer.

### 2. Description of Related Art

With the advancement of manufacturing technology in the electronics industry, in recent years, electronic products have been developing in the direction of thin, light and small in shape and in the direction of high performance, high functionality and high speed in function. Therefore, in order to meet the high integration and miniaturization needs of semiconductor devices, package substrates having high-density and fine-pitch wirings are often used in the packaging process.

As shown in FIG. 1, a conventional package substrate 1 includes a dielectric layer 11 having a first surface 111 and a second surface 112 opposing the first surface 111, a first circuit layer 12 formed on the first surface 111, a second circuit layer 13 formed on the second surface 112 and a plurality of conductive blind vias 14 formed in the dielectric layer 11 and electrically connected to the first circuit layer 12 and the second circuit layer 13. Thereafter, an insulating protective layer 15 having openings exposing portions of the first circuit layer 12 and the second circuit layer 13 is respectively formed on the first surface 111 and the second surface 112. Moreover, a conductive bump 16, 16′ is formed in each of the openings for a chip 9 to be electrically connected to the second circuit layer 13 via the plurality of conductive bumps 16′ of the openings of the insulating protective layer 15 on the second circuit layer 13. The package substrate 1 can be further disposed on a printed circuit board (PCB) 8 via each of the conductive bumps 16 provided on the first circuit layer 12.

However, the conventional package substrate 1 is formed by forming holes penetrating through the dielectric layer 11 from the first surface 111 to the second surface 112 and then filling the holes with a conductive material to form each of the conductive blind vias 14. Therefore, as shown in FIG. 1, each of the conductive blind vias 14 is usually limited by a wider diameter of the wiring at the first surface 111, and thus the adjacent conductive blind vias 14 usually have to maintain a wider spacing between them. As such, it is not possible to satisfy the demand for high-density and fine-pitch wirings.

Therefore, how to overcome the various problems of the above-mentioned conventional technology manufacturing methods has become an urgent issue to be solved.

### SUMMARY

In view of the various shortcomings of the aforementioned conventional technologies, the present disclosure provides a method of manufacturing a package substrate, which comprises: forming a first circuit layer on a first metal layer; forming a first dielectric layer on the first metal layer and the first circuit layer, wherein the first dielectric layer is defined with a first surface and a second surface opposing the first surface, and the first surface contacts the first metal layer; forming a first build-up circuit on the second surface of the first dielectric layer and forming a plurality of first conductive blind vias in the first dielectric layer, so as to be electrically connecting the first circuit layer to the first build-up circuit via the plurality of first conductive blind vias; forming a plurality of second conductive blind vias in the first dielectric layer from the first surface to electrically connect the first build-up circuit; and removing the first metal layer to expose the first surface of the first dielectric layer, each of the first conductive blind vias and each of the second conductive blind vias.

In one embodiment of the aforementioned manufacturing method of the package substrate, the first metal layer is bonded to a carrier board.

In one embodiment of the aforementioned manufacturing method of the package substrate, the carrier board is a copper foil substrate.

In one embodiment of the aforementioned manufacturing method of the package substrate, the formation of the first conductive blind vias comprises forming a second metal layer on the second surface of the first dielectric layer; forming a plurality of first holes penetrating through the first dielectric layer from the second metal layer to the second surface of the first dielectric layer by means of a laser; and filling the plurality of first holes with a conductive material to form the first conductive blind vias.

In one embodiment of the aforementioned manufacturing method of the package substrate, the formation of the first build-up circuit comprises forming a patterned resist layer on the second metal layer and exposing portions of the second metal layer and the plurality of first holes after forming the plurality of first holes penetrating through the first dielectric layer; forming the conductive material on the exposed portions of the second metal layer and filling the plurality of first holes with the conductive material to form the first build-up circuit; and forming the plurality of first conductive blind vias electrically connected to the first circuit layer and the first build-up circuit.

In one embodiment of the aforementioned manufacturing method of the package substrate, the formation of the second conductive blind vias comprises forming a plurality of second holes penetrating through the first dielectric layer from the first metal layer to the first surface of the first dielectric layer by means of a laser; and filling the plurality of second holes with a conductive material to form the second conductive blind vias.

In one embodiment of the aforementioned manufacturing method of the package substrate, the first conductive blind vias and the second conductive blind vias that are exposed from the first surface of the first dielectric layer have the same line width.

In one embodiment of the aforementioned manufacturing method of the package substrate, the method further includes forming a second dielectric layer on the second surface of the first dielectric layer and forming a second build-up circuit on a surface of the second dielectric layer; and forming a plurality of third conductive blind vias in the second dielectric layer to electrically connect the first build-up circuit and the second build-up circuit.

In one embodiment of the aforementioned manufacturing method of the package substrate, the methodfurther includes forming an insulating protective layer on the first surface of the first dielectric layer and on the surface of the second dielectric layer, respectively, wherein the insulating protective layer has a plurality of apertures to expose portions of the second build-up circuit as well as each of the first conductive blind vias and each of the second conductive blind vias.

In one embodiment of the aforementioned manufacturing method of the package substrate, the method further includes forming a conductive bump in each of the apertures.

As can be seen from the above, the manufacturing method of the package substrate of the present disclosure mainly forms the second conductive blind vias and the first conductive blind vias from the first surface and the second surface of the first dielectric layer respectively, in order to achieve the purpose of enhancing the wiring density.

### BRIEF DESCRIPTION OF THE DRAWINGS

FIG. 1 is a schematic cross-sectional view showing a conventional package substrate.

FIG. 2A to FIG. 2M are schematic cross-sectional views illustrating a method of manufacturing a package substrate according to the present disclosure.

FIG. 3 is a schematic cross-sectional view showing the practical application of the package substrate according to the present disclosure.

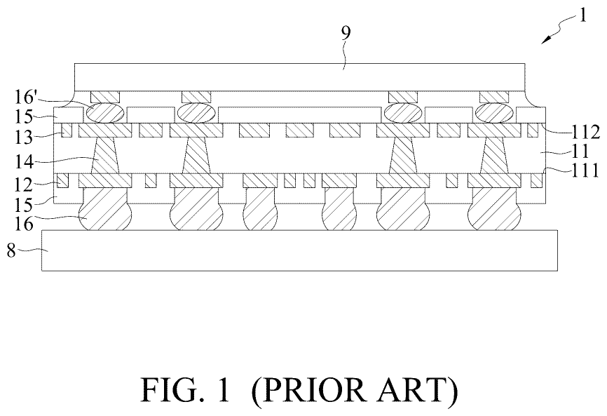

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

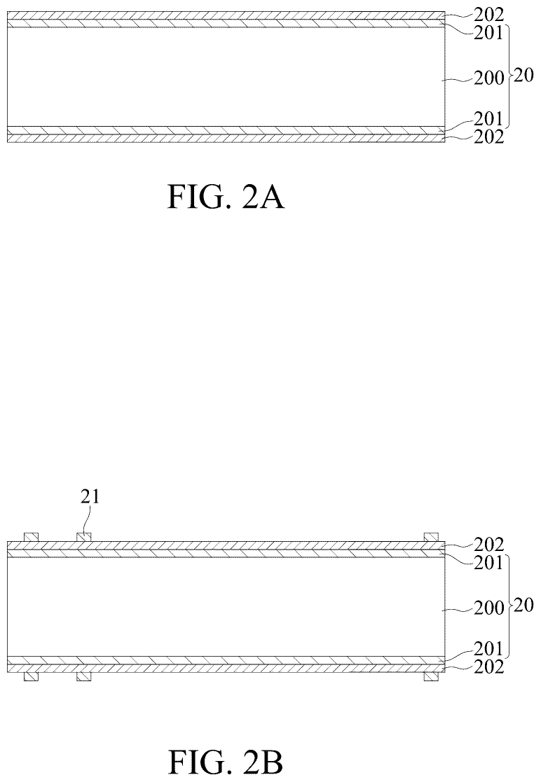

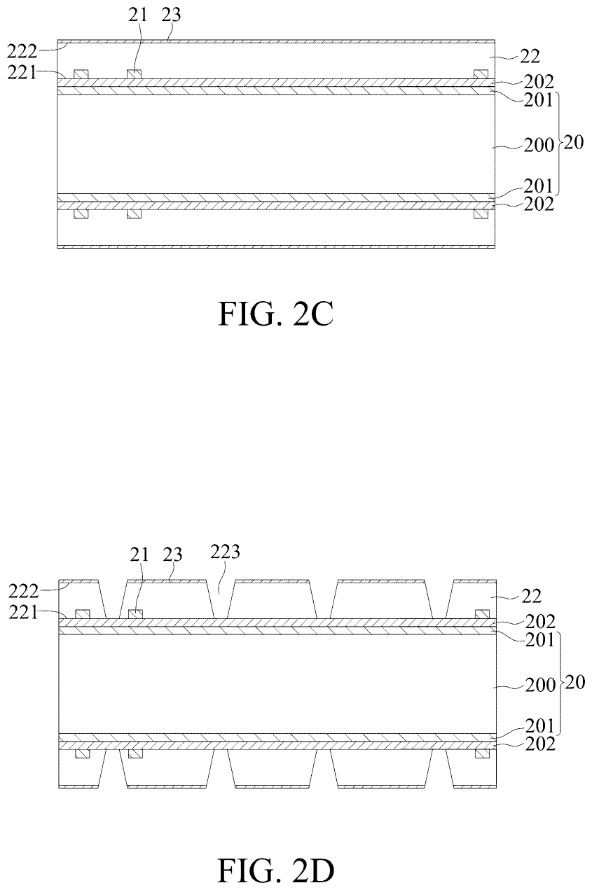

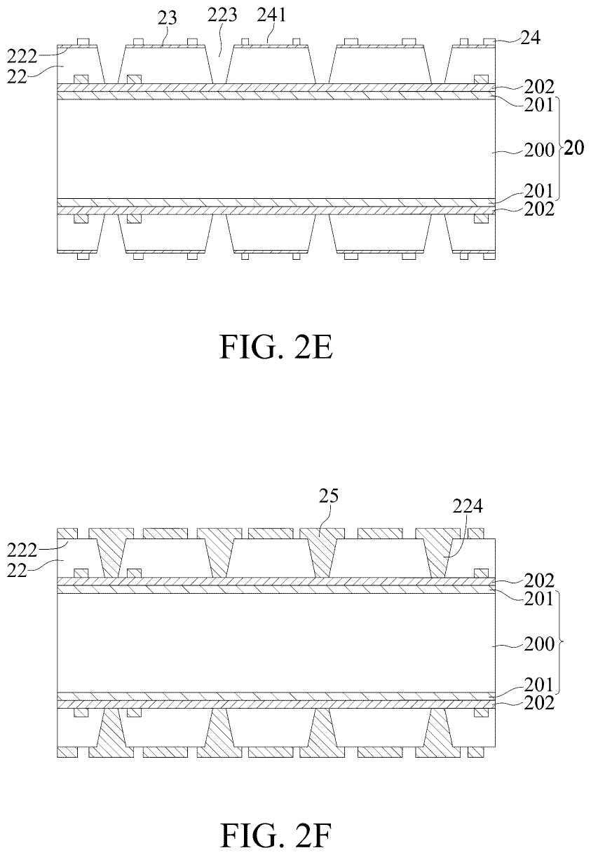

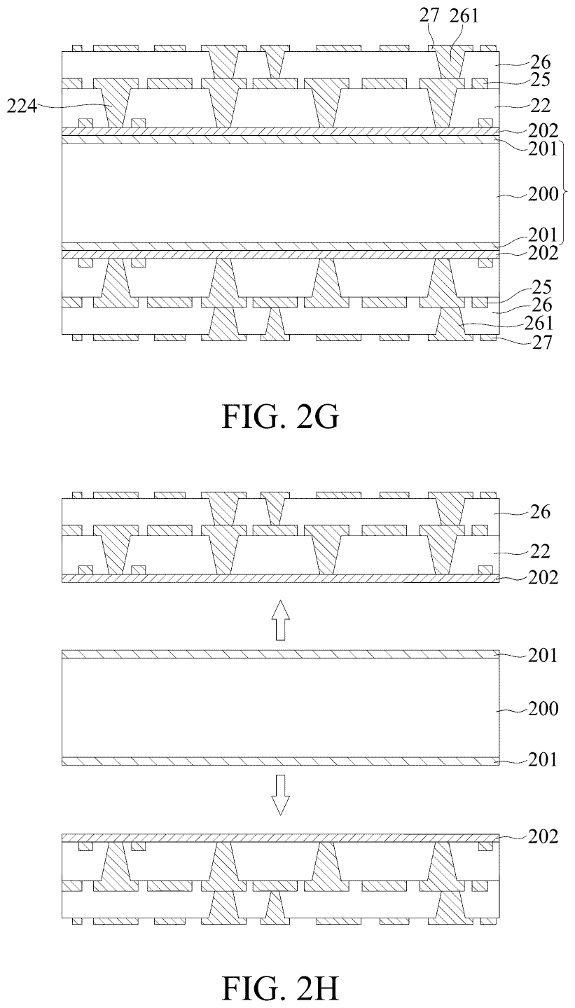

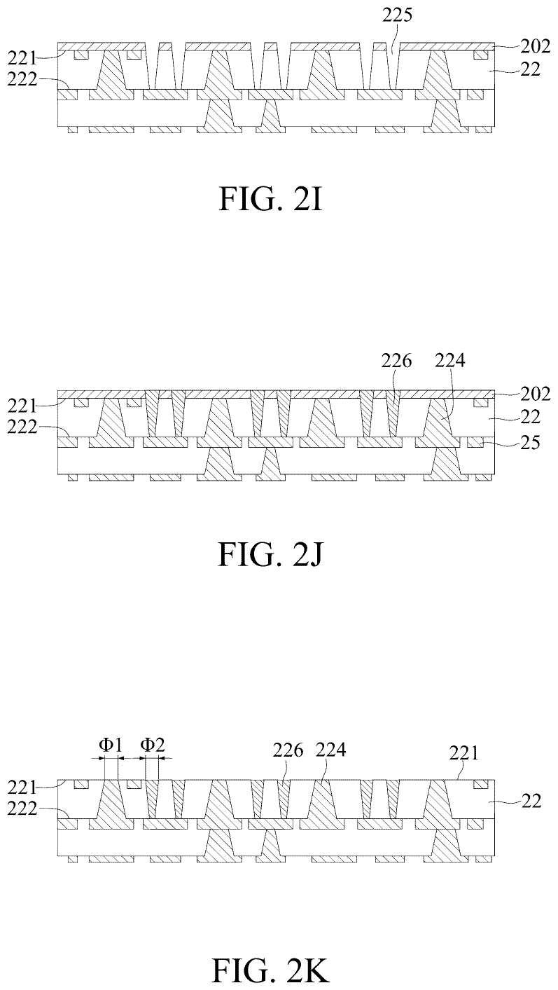

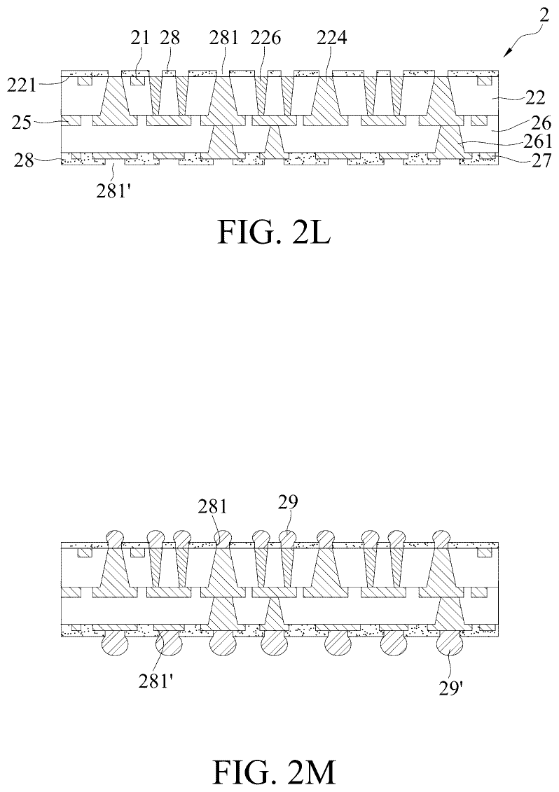

FIG. 2A to FIG. 2M are schematic cross-sectional views illustrating a method of manufacturing a package substrate according to the present disclosure.

As shown in FIG. 2A, a carrier board 20 is provided, wherein the carrier board may be a copper foil substrate.

In detail, the carrier board 20 includes an insulating board body 200 and a copper foil 201 formed on opposing surfaces of the insulating board body 200. In addition, at least one first metal layer 202 is bonded to the copper foil 201 on at least one side of the insulating board body 200.

In an embodiment, as shown in FIG. 2A, the first metal layer 202 is formed on both the upper side and the lower side of the insulating board body 200, wherein the process performed on each of the first metal layers 202 is the same, and therefore, the following is illustrated only with one side of the first metal layer 202.

As shown in FIG. 2B, a first circuit layer 21 is formed on the first metal layer 202.

As shown in FIG. 2C, a first dielectric layer 22 is formed on the first metal layer 202 and the first circuit layer 21 to cover the first metal layer 202 and the first circuit layer 21, wherein the first dielectric layer 22 has a first surface 221 and a second surface 222 opposing the first surface 221, whereby the first surface 221 is brought into contact with the first metal layer 202, the first circuit layer 21 is embedded in the first dielectric layer 22, and the first circuit layer 21 is flush with the first surface 221 of the first dielectric layer 22, and at the same time, a portion of the first circuit layer 21 is exposed from the first dielectric layer 22.

Subsequently, as shown in FIG. 2C to FIG. 2F, a first build-up circuit 25 is formed on the second surface 222 of the first dielectric layer 22, and a plurality of the first conductive blind vias 224 are formed in the first dielectric layer 22 to be electrically connected to the first circuit layer 21 and the first build-up circuit 25. The details are described as below.

As shown in FIG. 2C, a second metal layer 23 is formed on the second surface 222 of the first dielectric layer 22.

As shown in FIG. 2D, first holes 223 are formed in the second metal layer 23 and the first dielectric layer 22 to expose the first metal layer 202 and the first circuit layer 21.

As shown in FIG. 2E, after forming a plurality of first holes 223 penetrating through the first dielectric layer 22, a patterned resist layer 24 is formed on the second metal layer 23. The patterned resist layer 24 has openings 241 that expose the second metal layer 23, thereby exposing portions of the second metal layer 23 and the plurality of first holes 223.

As shown in FIG. 2F, the conductive material is formed on the exposed portions of the second metal layer 23 and the conductive material is filled in the plurality of first holes 223 to form the first build-up circuit 25 on the second metal layer 23 (as shown in FIG. 2E). In addition, a plurality of first conductive blind vias 224 are formed in the first dielectric layer 22 to be electrically connected to the first circuit layer 21 (as shown in FIG. 2D) and the first build-up circuit 25. Thereafter, the patterned resist layer 24 is removed.

In an embodiment, first holes 223 (shown in FIG. 2D) penetrating through the first dielectric layer 22 may be formed by a laser process from the second metal layer 23 and the second surface 222 of the first dielectric layer 22, and a conductive material is formed by electroplating in the first holes 223 to form the first conductive blind vias 224.

As shown in FIG. 2G, a second dielectric layer 26 is further formed on the second surface 222 of the first dielectric layer 22, and a second build-up circuit 27 is formed on the surface of the second dielectric layer 26. In addition, a plurality of third conductive blind vias 261 may be further formed in the second dielectric layer 26 to be electrically connected to the first build-up circuit 25 and the second build-up circuit 27.

In other embodiments, depending on the requirements, it is possible to choose not to have any other dielectric layers and build-up circuits, or to add multiple dielectric layers and build-up circuits, such as a third dielectric layer and a third build-up circuit (not shown).

As shown in FIG. 2H, the insulating board body 200 and the copper foil 201 are removed to expose the first metal layer 202.

As shown in FIG. 2I, a plurality of second holes 225 are formed from the first metal layer 202 and the first surface 221 of the first dielectric layer 22 to the second surface 222.

As shown in FIG. 2J, a second conductive blind via 226 is formed in each of the second holes 225 (as shown in FIG. 2H), that is, a plurality of the second conductive blind vias 226 are formed in the first dielectric layer 22 from the first surface 221 to be electrically connected to the second circuit layer 25.

In an embodiment, the second conductive blind vias 226 may be formed by utilizing a reversed laser process to form the second holes 225 penetrating through the first dielectric layer 22 from the first metal layer 202 and the first surface 221 of the first dielectric layer 22, and the second holes 225 are filled with a conductive material to form the second conductive blind vias 226. Accordingly, the present disclosure further forms the second conductive blind vias 226 between two adjacent first conductive blind vias 224 by performing a reversed laser process on the first surface 221 to achieve the purpose of increasing the wiring density.

As shown in FIG. 2K, the first metal layer 202 is removed, and the first surface 221 of the first dielectric layer 22, each of the first conductive blind vias 224 and each of the second conductive blind vias 226 are exposed.

In an embodiment, each of the first conductive blind vias 224 and each of the second conductive blind vias 226 exposed from the first surface 221 of the first dielectric layer 22 have the same line width, that is, the line width Ø1 of each of the first conductive blind vias 224 is equal to the line width @2 of each of the second conductive blind vias 226. Moreover, the width of the end of each of the second conductive blind vias 226 on the second surface 222 is smaller than the width of the end of each of the first conductive blind vias 224 on the second surface 222.

As shown in FIG. 2L, an insulating protective layer 28 is respectively formed on the first surface 221 of the first dielectric layer 22 and the surface of the second dielectric layer 26 to form a package substrate 2 of the present disclosure, wherein the insulating protective layer 28 on the first surface 221 has a plurality of apertures 281 exposing each of the first conductive blind vias 224 and each of the second conductive blind vias 226. The insulating protective layer 28 on the surface of the second dielectric layer 26 has a plurality of apertures 281′ exposing the second build-up circuit 27. In an embodiment, the insulating protective layer 28 may optionally not be formed in the package substrate 2 of the present disclosure. Alternatively, in a specific embodiment, the insulating protective layer 28 may be a photosensitive polyimide (PSPI) solder resist material.

As shown in FIG. 2M, after forming each of the apertures 281, 281′, a conductive bump 29, 29′ may further be formed in each of the apertures 281, 281′.

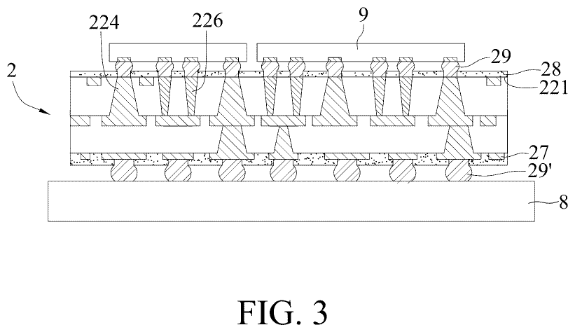

As shown in FIG. 3, in practice, the package substrate 2 manufactured by the above processes can be used for a chip 9 to be provided on the first surface 221 by means of each of the conductive bumps 29 and to be provided on a printed circuit board (PCB) 8 by means of each of the conductive bumps 29′ on the third circuit layer 27. Accordingly, since the package substrate 2 of the present disclosure provides dense wiring via each of the first conductive blind vias 224 and each of the second conductive blind vias 226, it can cope with the design of a higher density of solder balls on the chip 9, and with the use of the insulating protective layer 28 having high-resolution opening, it can be suitable for the purpose of the package substrate requirements, such as a small chip (Chiplet).

In summary, in the present disclosure, after forming first conductive blind vias on a second surface of a first dielectric layer, second holes are further provided on a first surface, and second conductive blind vias are formed, thereby providing a finer wiring. Accordingly, a high-density circuit design can be formed on a die-placing side (e.g., the first surface). Therefore, the present disclosure can form a high-density wiring by a simple process, thereby achieving the purpose of a high-density and fine-pitch wiring. In addition, the present disclosure forms each of the second conductive blind vias from the first surface by means of a reversed laser process for the purpose of forming uniformly sized and denser soldering pads on the die-placing side.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A method of manufacturing a package substrate, comprising:
forming a first circuit layer on a first metal layer;
forming a first dielectric layer on the first metal layer and the first circuit layer, wherein the first dielectric layer is defined with a first surface and a second surface opposing the first surface, and the first surface contacts the first metal layer;
forming a first build-up circuit on the second surface of the first dielectric layer and forming a plurality of first conductive blind vias in the first dielectric layer, so as to be electrically connecting the first circuit layer to the first build-up circuit via the plurality of first conductive blind vias;
forming a plurality of second conductive blind vias in the first dielectric layer from the first surface to electrically connect the first build-up circuit; and
removing the first metal layer to expose the first surface of the first dielectric layer, each of the first conductive blind vias and each of the second conductive blind vias.

2. The method of claim 1, wherein the first metal layer is bonded to at least one side of an insulating board body, and the first metal layer and the insulating board body form a carrier board.

3. The method of claim 2, wherein the carrier board is a copper foil substrate.

4. The method of claim 1, wherein the formation of the first conductive blind vias comprises forming a second metal layer on the second surface of the first dielectric layer; forming a plurality of first holes penetrating through the first dielectric layer from the second metal layer to the second surface of the first dielectric layer by means of a laser; and filling the plurality of first holes with a conductive material to form the first conductive blind vias.

5. The method of claim 4, wherein the formation of the first build-up circuit comprises forming a patterned resist layer on the second metal layer and exposing portions of the second metal layer and the plurality of first holes after forming the plurality of first holes penetrating through the first dielectric layer; forming the conductive material on the exposed portions of the second metal layer and filling the plurality of first holes with the conductive material to form the first build-up circuit; and forming the plurality of first conductive blind vias electrically connected to the first circuit layer and the first build-up circuit.

6. The method of claim 1, wherein the formation of the second conductive blind vias comprises forming a plurality of second holes penetrating through the first dielectric layer from the first metal layer to the first surface of the first dielectric layer by means of a laser; and filling the plurality of second holes with a conductive material to form the second conductive blind vias.

7. The method of claim 1, wherein the first conductive blind vias and the second conductive blind vias that are exposed from the first surface of the first dielectric layer have the same line width.

8. The method of claim 1, further comprising: forming a second dielectric layer on the second surface of the first dielectric layer and forming a second build-up circuit on a surface of the second dielectric layer; and forming a plurality of third conductive blind vias in the second dielectric layer to electrically connect the first build-up circuit and the second build-up circuit.

9. The method of claim 8, further comprising: forming an insulating protective layer on the first surface of the first dielectric layer and on the surface of the second dielectric layer, respectively, wherein the insulating protective layer has a plurality of apertures to expose portions of the second build-up circuit as well as each of the first conductive blind vias and each of the second conductive blind vias.

10. The method of claim 9, further comprising: forming a conductive bump in each of the apertures.
